(19) United States
(12) Patent Application Publication
(10) Pub. No.: US 2023/0176560 A1
(43) Pub. Date: Jun. 8, 2023

(54) EDGE-CLOUD COLLABORATIVE FAULT DETECTION METHOD FOR LOW-VOLTAGE DISTRIBUTION NETWORK BASED ON RANDOM MATRIX THEORY

(71) Applicant: Zhejiang University, Hangzhou (CN)

(72) Inventors: Zhiyi Li, Hangzhou (CN); Bihuan Li, Hangzhou (CN); Ping Ju, Nanjing (CN); Wenhai Wang, Hangzhou (CN)

(21) Appl. No.: 18/071,216

(22) Filed: Nov. 29, 2022

(30) Foreign Application Priority Data
Dec. 2, 2021 (CN) 2021114589011

(51) Int. Cl. G05B 23/02; H04L 67/12

(52) U.S. Cl. CPC G05B 23/0259; H04L 67/12

(57) ABSTRACT

The present invention discloses an edge-cloud collaborative fault detection method for a low-voltage distribution network based on a random matrix theory. An edge-cloud collaborative way is adopted, including fast fault detection running in an edge IoT agent and fault timing and locating analysis running in a distribution network control center. At an edge IoT terminal, the fault is quickly detected based on time-delay correlation analysis, a long-time series model is constructed, a time series is fitted with an autoregressive moving average model, and the fault is quickly judged based on a typical value of a limit spectral density function of the time series; after the edge IoT terminal detects the fault, fault-related data are uploaded to the distribution network control center through data screening, historical data and real-time data are integrated, and a spectral deviation index is configured to perform fault timing and locating analysis.

### TECHNICAL FIELD

The present invention belongs to the technical field of electrical engineering, and in particular relates to an edge-cloud collaborative fault detection method for low-voltage distribution network based on random matrix theory.

### BACKGROUND

The low-voltage distribution network is a connection link between a power system and power users, with many branches and difficult fault analysis. Statistics show that most power outages suffered by the power users are caused by distribution line faults. By accurately locating the faults, isolating the faults in time and restoring power supply in non-fault regions as soon as possible, power supply reliability of the distribution network can be effectively improved. However, compared with a transmission network, the connotation of fault detection in the distribution network is broader and the mechanism is more complex, so that the corresponding research work has important theoretical and engineering values.

Traditional fault locating technologies are mainly rooted in a matrix algorithm and an intelligent optimization algorithm. However, due to the frequent occurrence of problems such as unknown topology and chaotic wiring in a low-voltage distribution network, the harsh operating environment leads to the easy distortion of fault features, and it is difficult to accurately determine fault locations and types. With the application of an active distribution network technology, lines are gradually equipped with real-time commutation and connection capabilities, and topology adjustment flexibility of the distribution network is further enhanced. However, traditional fault locating methods generally rely on fixed topology information, and their applicability and accuracy are severely challenged. With digital transformation of the power system, a large number of measurement data enables a data-driven idea to be more feasible. The random matrix theory is an important way to integrate and analyze high-dimensional data, and is also an effective means to detect system situation anomalies. However, the application of the random matrix theory in the distribution network is in the ascendant. It is worth pointing out that the existing methods mainly process multi-source measurement information by means of centralized analysis, which leads to a large amount of analysis data and high computing complexity, and it is difficult to meet the real-time demand of measurement big data analysis in the low-voltage distribution network.

### SUMMARY

The object of the present invention is to provide an edge-cloud collaborative fault detection method for a low-voltage distribution network based on a random matrix theory, aiming at shortcomings of the prior art. Based on the random matrix theory, in combination with performance characteristics of edge computing, the present invention uses edge computing (edge) and centralized computing (cloud) to collaboratively detect faults of the distribution network, so as to achieve the purposes of accurately judging the faults and quickly locating the faults.

The object of the present invention is achieved by the following technical solution: an edge-cloud collaborative fault detection method for a low-voltage distribution network based on a random matrix theory includes the following steps:

(1) performing, by an edge Internet of Things (IoT) terminal, edge computing based on local measurement data, constructing a long-time series model for edge computing, solving an edge computing correlation matrix, fitting a long-time series by an autoregressive moving average (ARMA) model, determining orders of the ARMA model by Bayesian information criterion, solving a spectral density function of the ARMA model, solving a limit spectral density of the edge computing correlation matrix by the spectral density function of the ARMA model, solving a limit spectral density value at a typical value by a fast solution algorithm, and comparing with a threshold value, so as to quickly judge whether a fault occurs;

(2) deciding, by the edge IoT terminal, whether to upload data to a distribution network control center according to whether the fault is detected by a fault rapid detection method; if the edge computing detects the fault, uploading, by the edge IoT terminal, fault-related real-time data capable of reflecting the fault to the distribution network control center; otherwise, judging, by the edge IoT terminal, whether to upload measurement data at this moment as historical data according to a transmission interval, that is, uploading, by the edge IoT terminal, the data as the historical data at a lower frequency when no fault occurs;

(3) starting, after the distribution network control center receives a fault alarm of the edge IoT terminal, to perform centralized computing to determine time and place of the fault, constructing a high-dimensional sampling matrix model, and firstly performing timing analysis on the fault; fusing the historical data and the real-time data to acquire a plurality of time series, combining, after difference and normalization, the plurality of time series into a centralized computing sampling matrix, processing the sampling matrix by using a sliding window to acquire a window matrix, computing the spectral deviation degree of the window matrix at different moments, and determining the time of the fault according to a computing result of the spectral deviation degree; and

(4) the centralized computing of the distribution network control center including not only timing analysis, but also locating analysis; firstly, fusing the historical data and the real-time data to acquire a plurality of time series from a plurality of nodes, selecting the time series of any node and copying for many times to acquire a node expansive matrix, superimposing white noise on the node expansive matrix to acquire a locating analysis matrix, computing a spectral deviation degree value of the locating analysis matrix, and further computing the improved spectral deviation degree; then, traversing all nodes, computing the improved spectral deviation degrees of all nodes according to the above steps to find the node with the largest improved spectral deviation degree value, and determining such node as the place where the fault occurs.

Further, a computing formula for the long-time series model to computer the edge computing correlation matrix is as follows:

$$\hat{S} = \frac{r}{T} {\hat{X}}_{s} {\hat{X}}_{S}^{T} = \frac{r}{T} ( \hat{Z} \hat{T} ) {( \hat{Z} \hat{T} )}^{T} = \frac{r}{T} \hat{Z} ( \hat{T} {\hat{T}}^{T} ) {\hat{Z}}^{T}$$

wherein Ŝ is the edge computing correlation matrix, \hat{X}_{S} is an edge computing measurement matrix,

$$\frac{T}{r}$$

is the number of columns of \hat{X}_{S}, \hat{Z} is a random matrix capable of being approximated as Gaussian distribution after normalization, \hat{T} is a linear transformation coefficient matrix capable of representing time-delay correlation of the long time series; a form of the edge computing measurement matrix k is as follows:

$${\hat{X}}_{S} = [ \begin{matrix}{x}_{1} & {x}_{2} & … & {x}_{T / r} \\ \begin{matrix}{x}_{T / r + 1} \\ ⋮\end{matrix} & \begin{matrix}{x}_{T / r + 2} \\ ⋮\end{matrix} & \begin{matrix}… \\ ⋱\end{matrix} & \begin{matrix}{x}_{2 T / r} \\ ⋮\end{matrix} \\ {x}_{( r - 1 ) T / r + 1} & {x}_{( r - 1 ) T / r + 2} & … & {x}_{T}\end{matrix} ]$$

wherein {x₁, x₂, . . . , x_{T}} is an element in the long time series xₑ with a length T=r×(T/r); a form of the linear transformation coefficient matrix \hat{T} is as follows:

$$\hat{T} = {[ \begin{matrix}{φ}_{n} & {φ}_{n - 1} & … & {φ}_{2} & {φ}_{1} & 0 & … & 0 \\ 0 & {φ}_{n} & … & {φ}_{3} & {φ}_{2} & {φ}_{1} & … & 0 \\ ⋮ & ⋱ & & ⋮ & ⋮ & & ⋱ & 0 \\ 0 & … & 0 & {φ}_{n} & {φ}_{n - 1} & … & … & {φ}_{1}\end{matrix} ]}^{T}$$

wherein φₖ is a linear transformation coefficient, and k=1, 2, . . . , n; the edge computing correlation matrix Ŝ is equivalent to a product of a constant and \hat{Z}(\hat{T}\hat{T}^{T})\hat{Z}^{T}.

Further, computing steps for the typical value of the limit spectral density of the edge computing correlation matrix are as follows:

(1a) for any positive real number x, taking real number α, computing initial iterative values z₀=x+jα and m₀ (z₀)=γ+jα, wherein x is the eigenvalue of the edge computing correlation matrix Ŝ, m(z) and z represent Stieltjes transformations of h(x) and x, the lower right corner mark is 0, representing the initial iterative value, and γ is any positive real number;

(1b) starting the iteration, and selecting the initial values zₛ=z₀ and mₛ (zₛ)=m₀ (z₀);

(1c) from s=1, computing g(mₛ (zₛ)) of the s^{th} iteration as follows:

$$g ( {m}_{s} ( {z}_{s} ) ) = \frac{1}{c} {\int }_{0}^{2 π} \frac{f ( ω )}{1 + {m}_{s} ( {z}_{s} ) f ( ω )} d ω$$

wherein m(z) and z represent the Stieltjes transformations of h(x) and x, the lower right corner mark s represents the number of iterations, f (ω) is the spectral density function of the corresponding ARMA model, and w is an angular frequency; c is a constant; g( ) represents a numerical algorithm function;

(1d) computing the iterative result of the Stieltjes transformation of the (s+1)^{th} limit spectral density:

$${m}_{s + 1} ( {z}_{s + 1} ) = \frac{1}{- {z}_{s} + g ( {m}_{s} ( {z}_{s} ) )}$$

(1e) repeating the steps (1c) to (1d) until |mₛ₊₁ (zₛ₊₁)−mₛ (zₛ)|<β, and enabling m_{f} (z) to be equal to mₛ₊₁ (zₛ₊₁); β being a convergence criterion, and m_{f} (z) being the Stieltjes transformation of the limit spectral density when iterated to convergence; and

(lf) solving the limit spectral density function value h(x) at x by Stieltjes inverse transformation;

$$h ( x ) = \frac{1}{π} Im ( {m}_{f} ( z ) )$$

wherein Im(m_{f} (z)) represents the imaginary part of m_{f} (z).

Further, in step (1a), the real number α∈ (10⁻⁶, 10⁻³).

Further, in step (1c), the constant c is equal to 1.

Further, a selection method for the fault-related real-time data is as follows:

(2a) for 12 types of measurement data of a three-phase current, a three-phase voltage, three-phase active power and three-phase reactive power, further computing a three-phase unbalanced current and a three-phase unbalanced voltage, wherein the three-phase unbalanced voltage and current are differences between a voltage and a current of the largest phase of the node and a three-phase average voltage and a three-phase average current respectively; for the above 14 types of measurement data, computing the typical value of the limit spectral density as a characteristic index;

(2b) if the three-phase unbalanced voltage and the three-phase unbalanced current do not exceed a threshold value, uploading voltage data that the index of the three-phase voltage and current surges and exceeds the threshold value;

(2c) if the three-phase unbalanced voltage and the three-phase unbalanced current exceed the threshold value, and the characteristic index of only one-phase current, active power and reactive power data surges and exceeds the threshold value, uploading the corresponding voltage data that the characteristic index of the single-phase voltage and current surges and exceeds the threshold value; and

(2d) if the three-phase unbalanced voltage and the three-phase unbalanced current exceed the threshold value, and the characteristic indexes of two-phase current, active power and reactive power data surge and exceed the threshold value, uploading the corresponding voltage data that the characteristic indexes of the two-phase voltage and current surge and exceed the threshold value.

Further, a construction method for the locating analysis matrix includes:

\tilde{X}_{Ei}=\tilde{X}ᵢ+E=[\tilde{x}ᵢ^{T}\tilde{x}ᵢ^{T} . . . \tilde{x}ᵢ^{T}]^{T}+E

wherein \tilde{x}ᵢ is a measurement time series associated with an i^{th} edge IoT terminal; \tilde{X}ᵢ is the corresponding expansive matrix, E is a random noise matrix equal to \tilde{X}ᵢ, and \tilde{X}_{Ei} is the locating analysis matrix.

Further, a computing formula for the improved spectral deviation degree is:

$${d}_{iS} = \frac{1}{{d}_{max} + {d}_{dif} - {d}_{i}}$$

wherein, d_{iS} is an improvement index of node i to an original spectral deviation degree dᵢ, that is, the improved spectral deviation degree; dₘₐₓ is the maximum value of the spectral deviation degrees of all nodes in the distribution network; and d_{dif} is a difference between dₘₐₓ and the second largest value of the spectral deviation degrees.

Compared with the prior art, the present invention has the following beneficial effects:

1. A full data-driven idea is adopted, and detailed physical parameters are not needed, which can avoid detailed modeling of a distribution network structure, and can adapt to complex working conditions of the distribution network with a flexible topology;

2. The idea of edge (edge computing)-cloud (centralized computing) collaborative analysis is adopted for data streams, which can effectively solve the problem of dimension disaster of traditional centralized data analysis and make full use of existing intelligent electric meter infrastructures, thereby effectively saving computing resources of the distribution network control center and the investment in communication bandwidths, reducing the redundant investment of distribution network measuring apparatuses, and improving the speed and accuracy of fault detection;

3. Based on the random matrix theory, an edge computing model considering the time-delay correlation of the measurement data is constructed, which can effectively improve the analysis accuracy of time series characteristics and the sensitivity of fault detection; a centralized computing model based on spatial correlation of the measurement data is constructed while timeliness and accuracy are kept, which can effectively improve the tolerance to abnormal situations such as data abnormality and communication packet loss; and

4. The present invention takes into account transformation and transition of the distribution network to an active distribution network, is suitable for future power system forms, and gives corresponding data stream models.

### BRIEF DESCRIPTION OF DRAWINGS

FIG. 1 is a frame diagram of a fault detection algorithm of the present invention;

FIG. 2 is a schematic diagram of a limit spectral density of an edge computing correlation matrix;

FIG. 3 is a schematic diagram of data streams of a fault detection system of a distribution network;

FIG. 4 is a schematic diagram of rules for edge computing to upload fault-related data; and

FIG. 5 is a schematic diagram of a sliding window of a centralized computing sampling matrix.

### DETAILED DESCRIPTION OF EMBODIMENTS

The present invention will be further explained in detail in combination with the drawings and specific embodiments below.

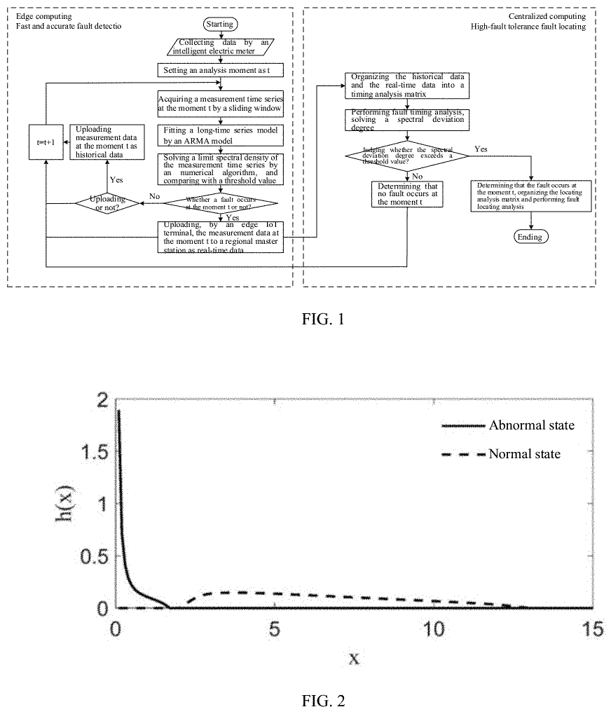

The edge-cloud collaborative fault detection method for a low-voltage distribution network based on a random matrix theory according to the present invention adopts an edge (edge computing)-cloud (centralized computing) collaborative way, and includes fast fault detection running in an edge IoT agent and fault timing and locating analysis running in the distribution network control center. A fault rapid detection method includes: at an edge IoT terminal, the fault is quickly detected based on time-delay correlation analysis, a long-time series model for edge computing is constructed, a time series is fitted with an autoregressive moving average model, and further the fault is quickly judged based on a typical value of a limit spectral density function of the time series; after the edge IoT terminal detects the fault, the fault-related data are uploaded to the distribution network control center through data screening, the distribution network control center integrates historical data and real-time data, a high-dimensional random matrix model for centralized computing is constructed, and a spectral deviation index is configured to perform fault timing and locating analysis. As shown in FIG. 1, the method includes the following steps:

(1) the edge IoT terminal performs edge computing based on data (local measurement data) collected by an intelligent electric meter; an analysis moment is set as t, a measurement time series with a length T at moment t is intercepted by a sliding window, the long-time series model for edge computing is constructed, the long-time series model is fitted by the ARMA model, orders of the ARMA model are determined by Bayesian information criterion, a spectral density function of the ARMA model is solved, and a limit spectral density of an edge computing correlation matrix is solved by a numerical algorithm, and compared with a threshold value, so as to quickly judge whether the fault occurs.

The edge computing correlation matrix is computed by the long time series model, and the edge computing correlation matrix S is equivalent to a product of a constant and \hat{Z}(\hat{T}\hat{T}^{T})\hat{Z}^{T}. The computing formula is:

$$\hat{S} = \frac{r}{T} {\hat{X}}_{s} {\hat{X}}_{S}^{T} = \frac{r}{T} ( \hat{Z} \hat{T} ) {( \hat{Z} \hat{T} )}^{T} = \frac{r}{T} \hat{Z} ( \hat{T} {\hat{T}}^{T} ) {\hat{Z}}^{T}$$

wherein Ŝ is the edge computing correlation matrix, \hat{X}_{S} is an edge computing measurement matrix, T is the number of elements in \hat{X}_{S}, r is the number of rows of \hat{X}_{S},

$$\frac{T}{r}$$

is the number of columns of \hat{X}_{S}, \hat{Z} is a random matrix capable of being approximated as Gaussian distribution after normalization, and \hat{T} is a linear transformation coefficient matrix capable of representing time-delay correlation of the long time series. The upper right corner mark T indicates transposition.

A form of the edge computing measurement matrix \hat{X}_{S} is as follows:

$${\hat{X}}_{S} = [ \begin{matrix}{x}_{1} & {x}_{2} & … & {x}_{T / r} \\ \begin{matrix}{x}_{T / r + 1} \\ ⋮\end{matrix} & \begin{matrix}{x}_{T / r + 2} \\ ⋮\end{matrix} & \begin{matrix}… \\ ⋱\end{matrix} & \begin{matrix}{x}_{2 T / r} \\ ⋮\end{matrix} \\ {x}_{( r - 1 ) T / r + 1} & {x}_{( r - 1 ) T / r + 2} & … & {x}_{T}\end{matrix} ]$$

wherein {x₁, x₂, . . . , x_{T}} is an element in the long time series xₑ with a length T=r×(T/r).

A form of the linear transformation coefficient matrix \hat{T} is as follows:

$$\hat{T} = {[ \begin{matrix}{φ}_{n} & {φ}_{n - 1} & … & {φ}_{2} & {φ}_{1} & 0 & … & 0 \\ 0 & {φ}_{n} & … & {φ}_{3} & {φ}_{2} & {φ}_{1} & … & 0 \\ ⋮ & ⋱ & & ⋮ & ⋮ & & ⋱ & 0 \\ 0 & … & 0 & {φ}_{n} & {φ}_{n - 1} & … & … & {φ}_{1}\end{matrix} ]}^{T}$$

wherein φₖ is a linear transformation coefficient, and k=1, 2, . . . , n.

The spectral density function of the ARMA model is needed to solve the limit spectral density of the edge computing correlation matrix Ŝ, so that the ARMA model is firstly configured to fit the time-delay correlation of the long-time series, and then the orders of the ARMA model are determined by the Bayesian information criterion. A BIC value in the Bayesian information criterion is computed as follows:

BIC=(p+q)ln(T)−2 ln(L)

wherein p and q are the orders of the ARMA model, L is a likelihood function, and Tis the length of the long time series.

The spectral density function of the ARMA model is combined to compute the limit spectral density of the edge computing correlation matrix Ŝ. The schematic diagram of the limit spectral density function h(x) in a normal state and a fault state is as shown in FIG. 2. The computing steps for computing the typical value of the limit spectral density of the edge correlation matrix are as follows:

(1a) for any positive real number x, taking a sufficiently small real number α, such as α∈ (10⁻⁶, 10⁻³), and computing initial iterative values z₀=x+jα and m₀ (z₀)=γ+jα, wherein x is an independent variable corresponding to the dependent variable h(x), a physical meaning thereof is an eigenvalue of the edge computing correlation matrix Ŝ, m(z) and z represent Stieltjes transformations of h(x) and x, the lower right corner mark represents the number of iterations, if being 0, the lower right corner mark represents the initial iterative value, and γ is any positive real number;

(1b) starting the iteration, and selecting the initial values zₛ=z₀ and mₛ (zₛ)=m₀ (z₀);

(1c) from s=1, computing g(mₛ (zₛ)) of the s^{th} iteration as follows:

$$g ( {m}_{s} ( {z}_{s} ) ) = \frac{1}{c} {\int }_{0}^{2 π} \frac{f ( ω )}{1 + {m}_{s} ( {z}_{s} ) f ( ω )} d ω$$

wherein m(z) and z represent the Stieltjes transformations of h(x) and x, the lower right corner mark represents the number of iterations, f (ω) is the spectral density function of the corresponding ARMA model, and co is an angular frequency; c is a constant and may be 1; s is the number of iterations and g( ) is to explain the function defined by the numerical algorithm conveniently;

(1d) computing the iterative result of the Stieltjes transformation of the (s+1)^{th} limit spectral density:

$${m}_{s + 1} ( {z}_{s + 1} ) = \frac{1}{- {z}_{s} + g ( {m}_{s} ( {z}_{s} ) )}$$

wherein m(z) and z represent the Stieltjes transformations of h(x) and x, and the lower right corner mark represents the number of iterations;

(1e) repeating the steps (1c) to (1d) until |mₛ₊₁ (zₛ₊₁)−mₛ (zₛ)|<β, and enabling m_{f}(z) to be equal to mₛ₊₁ (zₛ₊₁); β being a convergence criterion, and m_{f} (z) being the Stieltjes transformation of the limit spectral density when iterated to convergence; and

(1f) solving the limit spectral density function value h(x) at x by Stieltjes inverse transformation;

$$h ( x ) = \frac{1}{π} Im ( {m}_{f} ( z ) )$$

wherein Im(m_{f} (z)) represents the imaginary part of m_{f}(z); then, the typical value h(x) of the limit spectral density function is compared with the threshold value, to judge whether the fault occurs or not; if it is greater than the threshold value, the fault occurs, and if it is less than or equal to the threshold value, the fault does not occur; the threshold value is a product of the maximum value of h(x) in a historical normal state and a margin coefficient, and the margin coefficient may be 1.5.

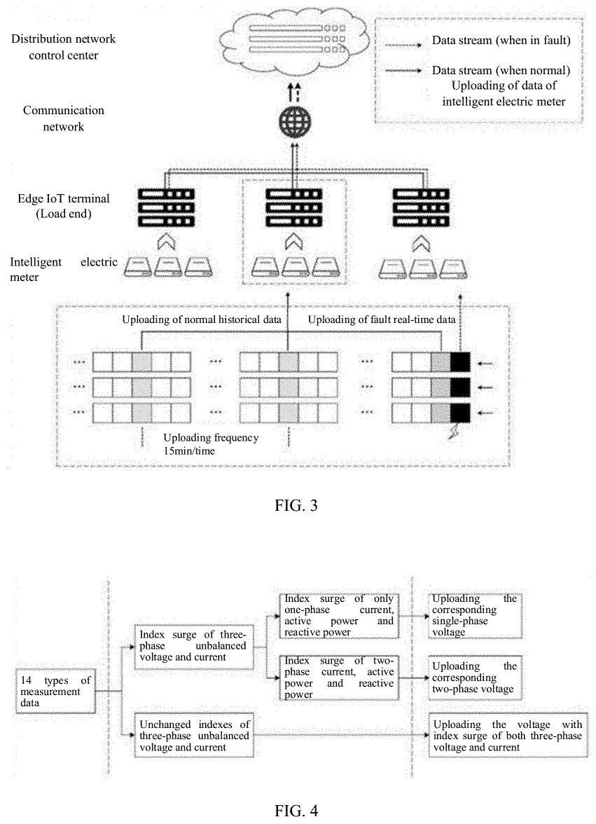

(2) The edge IoT terminal decides whether to upload data to the distribution network control center according to whether the fault is detected by the fault rapid detection method in step (1); if the edge computing detects the fault, the edge IoT terminal will upload the fault-related real-time data that can reflect the fault to the distribution network control center as real-time data; otherwise (no fault is detected), the edge IoT terminal judges whether to upload the measurement data at the moment t as historical data according to a set transmission interval (for example, once every 15 minutes), that is, the edge IoT terminal uploads the measurement data at the moment t as the historical data at a lower frequency when no fault occurs; then, when collecting new data, the system checks whether the fault occurs at moment t+1 according to the same steps. The data stream model between the edge IoT terminal and the distribution network control center is shown in FIG. 3.

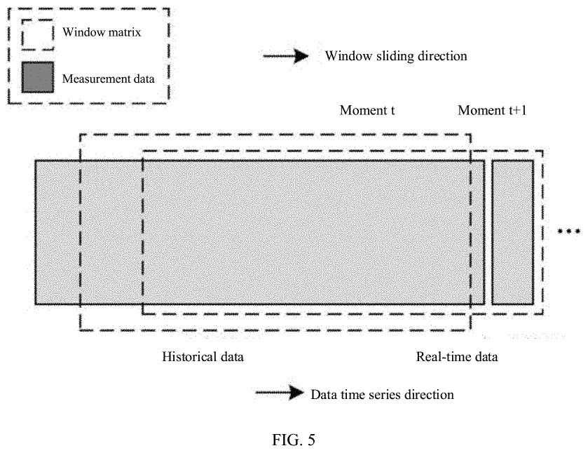

A logic diagram of selecting the fault-related real-time data is shown in FIG. 4, and the specific selection method includes:

(2a) for 12 types of measurement data of a three-phase current, a three-phase voltage, three-phase active power and three-phase reactive power, further computing a three-phase unbalanced current and a three-phase unbalanced voltage, wherein the three-phase unbalanced voltage and current are differences between a voltage and a current of the largest phase of the node and a three-phase average voltage and a three-phase average current respectively; for the above 14 types of measurement data, computing the limit spectral density as a characteristic index, wherein a long time series xₑ may be constructed for each type of measurement data, and then the spectral density function is computed according to step (1);

(2b) if the three-phase unbalanced voltage and the three-phase unbalanced current do not exceed (<) a threshold value, uploading voltage data that the characteristic index of the three-phase voltage and current surges and exceeds the threshold value;

(2c) if the three-phase unbalanced voltage and the three-phase unbalanced current exceed (>) the threshold value, and the characteristic index of only one-phase current, active power and reactive power data surge and exceed the threshold value, uploading the corresponding voltage data that the characteristic index of the single-phase voltage and current surges and exceeds the threshold value; and

(2d) if the three-phase unbalanced voltage and the three-phase unbalanced current exceed (>) the threshold value, and the characteristic indexes of two-phase current, active power and reactive power data surge and exceed the threshold value, uploading the corresponding voltage data that the characteristic indexes of the two-phase voltage and current surge and exceed the threshold value.

(3) After receiving a fault alarm of the edge IoT terminal, the distribution network control center starts to perform centralized computing to determine the time and place of the fault, and constructs a high-dimensional sampling matrix model.

Firstly, timing analysis is performed on the fault. The historical data and the real-time data are fused to acquire a plurality of time series. After difference and normalization, the multiple time series are combined into a centralized computing sampling matrix. The sliding window is configured to process the sampling matrix to acquire a window matrix, and a spectral deviation degree of the window matrix at different moments is computed. According to the computing result of the spectral deviation degree, the time of the fault is determined. The schematic diagram for the sliding window to intercept the window matrix is as shown in FIG. 5.

A computing formula for the window matrix is:

$${\tilde{X}}_{W} = [ \begin{matrix}{\tilde{x}}_{1 , t - {W}_{2} + 1} & {\tilde{x}}_{1 , t - {W}_{2} + 2} & … & {\tilde{x}}_{1 , t} \\ {\tilde{x}}_{2 , t - {W}_{2} + 1} & {\tilde{x}}_{2 , t - {W}_{2} + 2} & … & {\tilde{x}}_{2 , t} \\ ⋮ & ⋮ & ⋱ & ⋮ \\ {\tilde{x}}_{{n}^{′} , t - {W}_{2} + 1} & {\tilde{x}}_{{n}^{′} , t - {W}_{2} + 2} & … & {\tilde{x}}_{{n}^{′} , t}\end{matrix} ]$$

wherein \tilde{X}_{W} is the window matrix, W₂ is a length of the sliding window, t is the current moment, the corner markers 1, 2, . . . , n′ correspond to n′ nodes, and corner markers t−W₂+1, t−W₂+2, . . . , t represent W₂ moments.

A timing analysis correlation matrix is calculated from the window matrix \tilde{X}_{W}, and the computing formula is:

$${\tilde{S}}_{T} = \frac{1}{{W}_{2}} {\tilde{X}}_{W} {\tilde{X}}_{W}^{T}$$

wherein \tilde{X}_{W} is the window matrix, W₂ is the length of the sliding window, and \tilde{S}_{T} is the timing analysis correlation matrix.

The computing formula for the spectral deviation degree of \tilde{S}_{T} is:

d_{S}=(λₘₐₓ−\tilde{λ}ₘᵢₙ)²+(λₘₐₓ−\tilde{λ}ₘᵢₙ)²

wherein d_{S} is the spectral deviation degree, \tilde{λ}ₘₐₓ, \tilde{λ}ₘᵢₙ are maximum and minimum eigenvalues of \tilde{S} respectively; λₘₐₓ and λₘᵢₙ are theoretical maximum and minimum eigenvalues of an equal-scale random matrix respectively, wherein λₘₐₓ=(1₊\sqrt{c′})², λₘᵢₙ=(1₋\sqrt{c′})² and c′ is a row-column ratio of \tilde{X}_{W}.

The threshold value of the spectral deviation degree is selected as a product of the maximum spectral deviation degree in the historical normal state and the margin coefficient, and the margin coefficient may be 1.5. The moment when the spectral deviation degree surges and exceeds (>) the threshold value is the moment when the fault occurs.

(4) Besides the timing analysis, the centralized computing of the distribution network control center also includes locating analysis. If it is judged in step (3) that the fault occurs at the moment t, the locating analysis of the centralized computing includes the steps:

firstly, the historical data and the real-time data are fused to acquire a plurality of time series from a plurality of nodes, the time series of any node is selected and copied for many times to acquire a node expansive matrix, white noise is superimposed on the node expansive matrix to acquire a locating analysis matrix, a spectral deviation degree value of the locating analysis matrix is calculated, and further the improved spectral deviation degree is computed; then, all nodes are traversed to compute the improved spectral deviation degrees of all nodes according to the above steps, so as to find the node with the largest improved spectral deviation degree value, and such a node is determined as the place where the fault occurs.

A construction method for the locating analysis matrix is:

\tilde{X}_{Ei}=\tilde{X}ᵢ+E=[\tilde{x}ᵢ^{T}\tilde{x}ᵢ^{T} . . . \tilde{x}ᵢ^{T}]^{T}+E

wherein \tilde{x}ᵢ is a measurement time series associated with an i^{th} edge IoT terminal; \tilde{X}ᵢ is the corresponding expansive matrix, E is a random noise matrix equal to \tilde{X}ᵢ, and \tilde{X}_{Ei} is the locating analysis matrix.

A locating analysis correlation matrix is constructed from the locating analysis matrix, and the computing formula is:

$${\tilde{S}}_{L} = \frac{1}{{W}_{L}} {\tilde{X}}_{Ei} {\tilde{X}}_{Ei}^{T}$$

wherein, \tilde{S}_{L} is the locating analysis correlation matrix, and W_{L} is the number of columns of the locating analysis matrix \tilde{X}_{Ei}.

The spectral deviation degree dᵢ of \tilde{S}_{L} is computed, the computing method of dᵢ is the same as that of d_{S}, and the only difference is that the row-column ratio in the formula is selected as the row-column ratio of \tilde{X}_{Ei}. Further the improved spectral deviation degree is computed to find out the node with the largest spectral deviation degree. A computing formula for the improved spectral deviation degree is:

$${d}_{iS} = \frac{1}{{d}_{max} + {d}_{dif} - {d}_{i}}$$

wherein d_{iS} is an improvement index of node i to an original spectral deviation degree dᵢ, that is, the improved spectral deviation degree; dₘₐₓ is the maximum value of the spectral deviation degrees of all nodes in the distribution network; and d_{dif} is a difference between dₘₐₓ and the second largest value of the spectral deviation degrees of all nodes. The node with the largest improved spectral deviation degree value is found out, that is, the node where the fault is located.

What is claimed is:

1. An edge-cloud collaborative fault detection method for a low-voltage distribution network based on a random matrix theory, comprising the following steps:
(1) performing, by an edge Internet of Things (IoT) terminal, edge computing based on local measurement data, constructing a long-time series model for edge computing, solving an edge computing correlation matrix, fitting a long-time series by an autoregressive moving average (ARMA) model, determining orders of the ARMA model by Bayesian information criterion, solving a spectral density function of the ARMA model, solving a limit spectral density of the edge computing correlation matrix by the spectral density function of the ARMA model, solving a limit spectral density value at a typical value by a fast solution algorithm, and comparing with a threshold value, so as to quickly judge whether a fault occurs:
wherein the limit spectral density function value h(x) is:
$$h ( x ) = \frac{1}{π} Im ( {m}_{f} ( z ) )$$
in the formula, x is an eigenvalue of the edge computing correlation matrix, Im(m_{f}(z)) represents an imaginary part of m_{f}(z), and m_{f}(z) is Stieltjes transformation of the limit spectral density when iterated to convergence;
wherein the threshold value of a spectral deviation degree is selected as a product of the maximum spectral deviation degree in a historical normal state and a margin coefficient;
(2) deciding, by the edge IoT terminal, whether to upload data to a distribution network control center according to whether the fault is detected by a fault rapid detection method; if the edge computing detects the fault, uploading, by the edge IoT terminal, fault-related real-time data capable of reflecting the fault to the distribution network control center; otherwise, judging, by the edge IoT terminal, whether to upload measurement data at this moment as historical data according to a transmission interval, that is, uploading, by the edge IoT terminal, the data as the historical data at a lower frequency when no fault occurs;
(3) starting, after the distribution network control center receives a fault alarm of the edge IoT terminal, to perform centralized computing to determine time and place of the fault, constructing a high-dimensional sampling matrix model, and firstly performing timing analysis on the fault; fusing the historical data and the real-time data to acquire a plurality of time series, combining, after difference and normalization, the plurality of time series into a centralized computing sampling matrix, processing the sampling matrix by using a sliding window to acquire a window matrix, computing the spectral deviation degree of the window matrix at different moments, and determining the time of the fault according to a computing result of the spectral deviation degree; and
(4) the centralized computing of the distribution network control center including not only timing analysis, but also locating analysis; firstly, fusing the historical data and the real-time data to acquire a plurality of time series from a plurality of nodes, selecting the time series of any node and copying for many times to acquire a node expansive matrix, superimposing white noise on the node expansive matrix to acquire a locating analysis matrix, computing a spectral deviation degree value of the locating analysis matrix, and further computing the improved spectral deviation degree; then, traversing all nodes, computing the improved spectral deviation degrees of all nodes according to the above steps to find the node with the largest improved spectral deviation degree value, and determining such node as the place where the fault occurs;
wherein a computing formula for the improved spectral deviation degree is:
$${d}_{iS} = \frac{1}{{d}_{max} + {d}_{dif} - {d}_{i}}$$
in the formula, d_{iS} is an improvement index of node i to an original spectral deviation degree dᵢ, that is, the improved spectral deviation degree; dₘₐₓ is the maximum value of the spectral deviation degrees of all nodes in the distribution network; and d_{dif} is a difference between dₘₐₓ and the second largest value of the spectral deviation degrees.

2. The edge-cloud collaborative fault detection method for a low-voltage distribution network based on a random matrix theory according to claim 1, wherein a computing formula for the long-time series model to computer the edge computing correlation matrix is as follows:
$$\hat{S} = \frac{r}{T} {\hat{X}}_{S} {\hat{X}}_{S}^{T} = \frac{r}{T} ( \hat{Z} \hat{T} ) {( \hat{Z} \hat{T} )}^{T} = \frac{r}{T} \hat{Z} ( \hat{T} {\hat{T}}^{T} ) {\hat{Z}}^{T}$$
wherein Ŝ is the edge computing correlation matrix, \hat{X}_{S} is an edge computing measurement matrix,
$$\frac{T}{r}$$
is the number of columns of \hat{X}_{S}, \hat{Z} is a random matrix capable of being approximated as Gaussian distribution after normalization, \hat{T} is a linear transformation coefficient matrix capable of representing time-delay correlation of the long time series; a form of the edge computing measurement matrix \hat{X}_{S} is as follows:
$${\hat{X}}_{S} = [ \begin{matrix}{x}_{1} & {x}_{2} & … & {x}_{T / r} \\ {x}_{T / r + 1} & {x}_{T / r + 2} & … & {x}_{2 T / r} \\ ⋮ & ⋮ & ⋱ & ⋮ \\ {x}_{( r - 1 ) T / r + 1} & {x}_{( r - 1 ) T / r + 2} & … & {x}_{T}\end{matrix} ]$$
wherein {x₁, x₂, . . . , x_{T}} is an element in the long time series xₑ with a length T=r×(T/r); a form of the linear transformation coefficient matrix \hat{T} is as follows:
$$\hat{T} = {[ \begin{matrix}{φ}_{n} & {φ}_{n - 1} & … & {φ}_{2} & {φ}_{1} & 0 & … & 0 \\ 0 & {φ}_{n} & … & {φ}_{3} & {φ}_{2} & {φ}_{1} & … & 0 \\ ⋮ & ⋱ & & ⋮ & ⋮ & & ⋱ & 0 \\ 0 & … & 0 & {φ}_{n} & {φ}_{n - 1} & … & … & {φ}_{1}\end{matrix} ]}^{T}$$
wherein φₖ is a linear transformation coefficient, and k=1, 2, . . . , n; the edge computing correlation matrix Ŝ is equivalent to a product of a constant and \hat{Z}(\hat{T}\hat{T}^{T})\hat{Z}^{T}.

3. The edge-cloud collaborative fault detection method for a low-voltage distribution network based on a random matrix theory according to claim 1, wherein computing steps for the typical value of the limit spectral density of the edge computing correlation matrix are as follows:
(1a) for any positive real number x, taking real number α, computing initial iterative values z₀=x+jα and m₀ (z₀)=γ+jα, wherein x is the eigenvalue of the edge computing correlation matrix Ŝ, m(z) and z represent Stieltjes transformations of h(x) and x, the lower right corner mark is 0, representing the initial iterative value, and γ is any positive real number;
(1b) starting the iteration, and selecting the initial values zₛ=z₀ and mₛ (z)=m₀ (z₀);
(1c) from s=1, computing g(mₛ (zₛ)) of the s^{th} iteration as follows:
$$g ( {m}_{s} ( {z}_{s} ) ) = \frac{1}{c} {\int }_{0}^{2 π} \frac{f ( ω )}{1 + {m}_{s} ( {z}_{s} ) f ( ω )} d ω$$
wherein m(z) and z represent the Stieltjes transformations of h(x) and x, the lower right corner mark s represents the number of iterations, f (ω) is the spectral density function of the corresponding ARMA model, and ω is an angular frequency; c is a constant; g( ) represents a numerical algorithm function;
(1d) computing the iterative result of the Stieltjes transformation of the (s+1)^{th} limit spectral density:
$${m}_{s + 1} ( {z}_{s + 1} ) = \frac{1}{- {z}_{s} + g ( {m}_{s} ( {z}_{s} ) )}$$
(1e) repeating the steps (1c) to (1d) until |mₛ₊₁ (zₛ₊₁)−mₛ (zₛ)|<β, and enabling m_{f}(z) to be equal to mₛ₊₁ (zₛ₊₁); β being a convergence criterion, and m_{f}(z) being the Stieltjes transformation of the limit spectral density when iterated to convergence; and
(1f) solving the limit spectral density function value h(x) at x by Stieltjes inverse transformation;
$$h ( x ) = \frac{1}{π} Im ( {m}_{f} ( z ) )$$
wherein Im(m_{f} (z)) represents the imaginary part of m_{f} (z).

4. The edge-cloud collaborative fault detection method for a low-voltage distribution network based on a random matrix theory according to claim 3, wherein in step (1a), the real number α∈ (10⁻⁶, 10⁻³).

5. The edge-cloud collaborative fault detection method for a low-voltage distribution network based on a random matrix theory according to claim 3, wherein in step (1c), the constant c is equal to 1.

6. The edge-cloud collaborative fault detection method for a low-voltage distribution network based on a random matrix theory according to claim 1, wherein a selection method for the fault-related real-time data is as follows:
(2a) for 12 types of measurement data of a three-phase current, a three-phase voltage, three-phase active power and three-phase reactive power, further computing a three-phase unbalanced current and a three-phase unbalanced voltage, wherein the three-phase unbalanced voltage and current are differences between a voltage and a current of the largest phase of the node and a three-phase average voltage and a three-phase average current respectively; for the above 14 types of measurement data, computing the typical value of the limit spectral density as a characteristic index;
(2b) if the three-phase unbalanced voltage and the three-phase unbalanced current do not exceed a threshold value, uploading voltage data that the index of the three-phase voltage and current surges and exceeds the threshold value;
(2c) if the three-phase unbalanced voltage and the three-phase unbalanced current exceed the threshold value, and the characteristic index of only one-phase current, active power and reactive power data surges and exceeds the threshold value, uploading the corresponding voltage data that the characteristic index of the single-phase voltage and current surges and exceeds the threshold value; and
(2d) if the three-phase unbalanced voltage and the three-phase unbalanced current exceed the threshold value, and the characteristic indexes of two-phase current, active power and reactive power data surge and exceed the threshold value, uploading the corresponding voltage data that the characteristic indexes of the two-phase voltage and current surge and exceed the threshold value.

7. The edge-cloud collaborative fault detection method for a low-voltage distribution network based on a random matrix theory according to claim 1, wherein a construction method for the locating analysis matrix comprises:
\tilde{X}_{Ei}=\tilde{X}ᵢ+E=[\tilde{x}ᵢ^{T}\tilde{x}ᵢ^{T} . . . \tilde{x}ᵢ^{T}]^{T}+E
wherein \tilde{x}ᵢ is a measurement time series associated with an i^{th} edge IoT terminal; \tilde{X}ᵢ is the corresponding expansive matrix, E is a random noise matrix equal to \tilde{X}ᵢ, and \tilde{X}_{Ei}, is the locating analysis matrix.
